(19) United States
(12) Patent Application Publication
(10) Pub. No.: US 2003/0090185 A1
(43) Pub. Date: May 15, 2003

(54) Arc stack housing with arc plate latching mechanism

(76) Inventor: Hamid S. Abroy, Lexington, KY (US)

Correspondence Address: SQUARE D COMPANY, 1415 South Roselle Road, Palatine, IL, 60067, US

(21) Appl. No.: 10/003,370

(22) Filed: Nov. 15, 2001

(51) Int. Cl. H05K 7/18

(52) U.S. Cl. 312/333; 312/223.1; 312/351

(57) ABSTRACT

An apparatus for releasably securing a plurality of arc plates in an arc extinguishing chamber or arc stack. The arc stack includes a plurality of arc plates separated by an air gap. The arc plates slide into a slot in the arc stack housing. A stop member and a locking tab position and secure the arc plate in the housing. The arc plate engages the spring-like stop member and the locking tab, which restrain the arc plate from moving or vibrating after being locked in place.

### CROSS-REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

### Field of Invention

This invention pertains generally to arc stacks in electrical switches. More particularly, this invention pertains to an apparatus for housing and securing arc plates.

### BRIEF SUMMARY OF THE INVENTION

An apparatus for housing and securing a plurality of arc plates in an arc extinguishing chamber or arc stack is provided. The apparatus includes a latching mechanism that positively locks the arc plates, which are included in a switch arc stack for an electrical switch. Each of a plurality of arc plates in the arc stack are inserted in a slot defined by securing ledges extending from securing members or side walls. The arc stack slots have a rear stop that prevents the arc plate from being pushed through the stack and the slot has a locking tab that, when it returns to its normal position after the arc plate is inserted into the slot, positions and positively secures the arc plate in the stack. The rear stop and locking tab are resilient and apply force against the arc plate, preventing the arc plate from vibrating in the arc stack housing.

### BRIEF DESCRIPTION OF THE SEVERAL VIEWS OF THE DRAWINGS

The above-mentioned features of the invention will become more clearly understood from the following detailed description of the invention read together with the drawings in which:

FIG. 1 is a perspective view of a arc stack housing for the arc plates;

FIG. 2 is a cutaway view of the arc stack housing and one arc plate;

FIG. 3 is a perspective cutaway view of the arc stack housing; and

FIG. 4 is a perspective view of an arc plate.

### DETAILED DESCRIPTION OF THE INVENTION

An apparatus for housing and securing an arc plate in a arc extinguishing chamber or arc stack is disclosed. An arc stack includes a housing containing a plurality of arc plates.

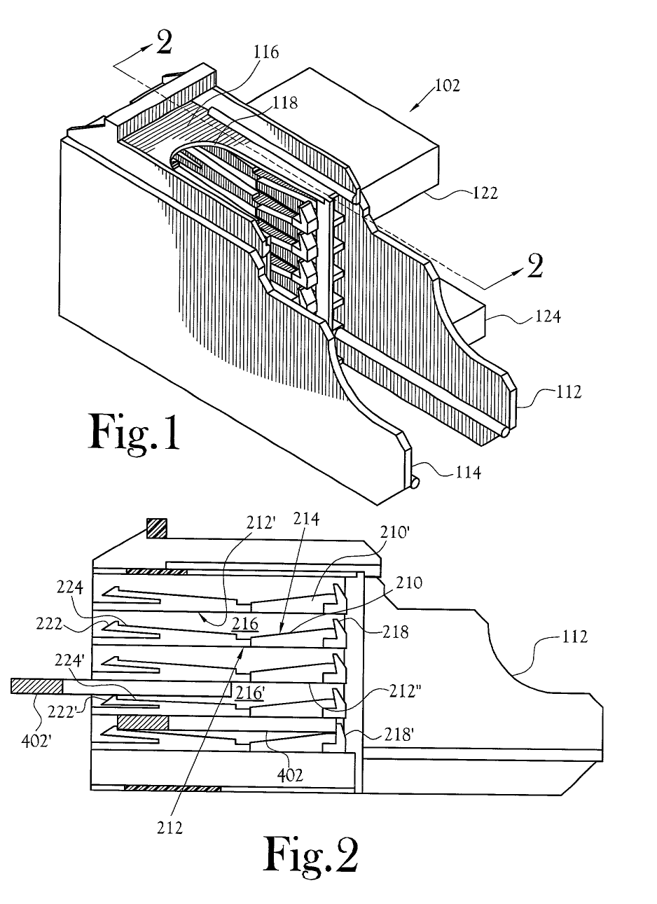

FIG. 1 illustrates an arc stack housing such as can be used in any blade type electrical switch. Those skilled in the art will recognize that arc stacks are used in many types of switches and the present invention is not limited to arc stacks having the illustrated configuration.

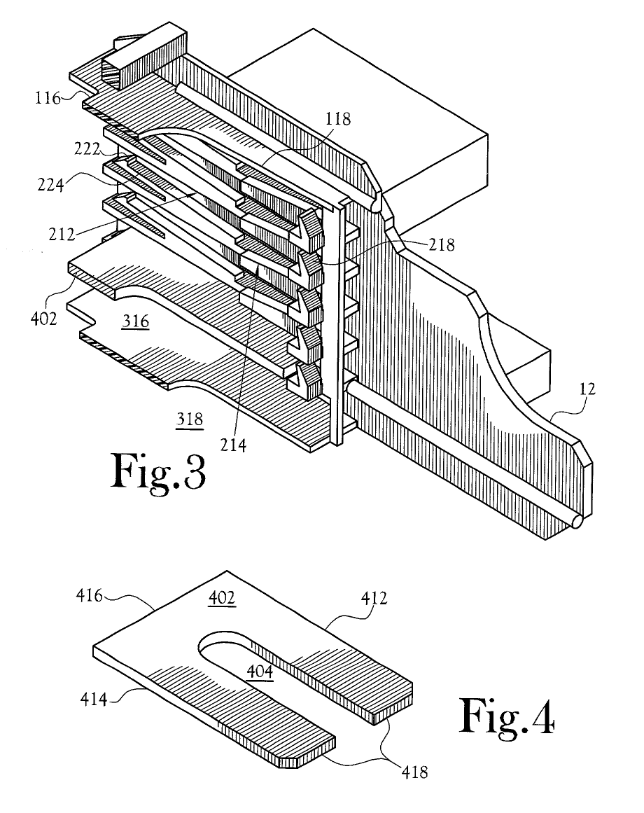

The illustrated arc stack housing 102 includes two substantially parallel housing walls 112 and 114. In the illustrated embodiment, the housing walls 112 and 114 are secured to each other in a spaced relationship by an upper member 116 and a lower member 316 (FIG. 3). The upper member 116 includes a longitudinal notch 118 that corresponds with the notches 404 in the arc plates 402 (FIG. 4). The lower member 316 has a longitudinal notch 318 that corresponds with the notches 404 in the arc plates 402. These notches, 118, 318 and 404, allow the switch blade (not illustrated) to pass freely through the arc stack. Also illustrated, in general, are protrusions 122 and 124 that are used for attaching and securing the arc stack housing 102 inside the switch. Those skilled in the art will recognize that the configuration of the arc stack housing 102 can vary to meet the configuration of the switch into which the arc stack is used without departing from the spirit and scope of the present invention.

FIG. 2 is a cut-away plan view showing the inside face of one wall 112. FIG. 3 is a cut-away perspective view showing the inside face of one wall 112. FIG. 2 illustrates a section of a fully installed arc plate 402 in the lowermost position and a partially installed arc plate 402′ in the adjacent upper position. FIG. 4 illustrates an arc plate 402, which has a leading end 418 with a notch 404, a pair of longitudinal edges 412 and 414, and a trailing end 416. FIGS. 2 and 3 illustrate five slots 216, and each slot 216 is adapted to receive an arc plate 402. Those skilled in the art will recognize that the number of slots 216 can vary without departing from the spirit and scope of the present invention.

The arc stack housing 102 includes members for securing a plurality of arc plates 402 in the housing 102. Referring to FIGS. 2 and 3, a number of generally parallel securing ledges 210 protrude from the housing wall 112. Each securing ledge 210 defines a lower surface 212 and an upper surface 214. The opposed upper surface 214 and lower surface 212′ of the generally parallel securing ledges 210 and 210′ define slots 216 into which the arc plates 402 slide. The longitudinal edge 412 of the arc plate 402 is adjacent to the housing wall 112 when the arc plate 402 is inserted into the slot 216. The slot 216 for receiving the uppermost arc plate 402 is defined by a space between the upper member 116 and the upper surface 214 of the uppermost securing ledge 210.

At one end of the slot is a stop member 218 that engages the leading edge 418 of the arc plate 402. The stop member 218 is resilient and deforms in the longitudinal direction of the slot 216, that is, the stop member 218 has shape memory whereby it is biased back toward its original shape when the deforming force is removed. At the opposite end of the slot 216 is a resilient locking arm 224 having a locking tab 222 that engages the trailing end 416 of the arc plate 402 when the arc plate 402 is fully installed in the slot 216. The locking arm 224′ resiliently deforms away from the opposed lower surface 212″ when the arc plate 402′ is inserted into the slot 216′, thereby ensuring that the locking tab 222′ does not impede the arc plate 402′ as it is being inserted into the slot and being positioned in the housing 102. When the arc plate 402 is positioned and secured in the slot 216, the locking tab 222 engages the trailing end 416 of the arc plate 402, which is forced against the locking tab 222 by the stop member 218′, and the locking arm 224 exerts a force against the arc plate 402, forcing the arc plate 402 against the opposed lower surface 212′.

The opposing surfaces of the stop member 218 and the locking tab 222 are separated by a distance that is less than the distance between the leading end 412 and the trailing end 416 of the arc plate 402. When the arc plate 402 is positioned and secured in the housing 102, the stop member 218′ is deformed in the longitudinal direction away from the arc plate 402, and the stop member 218′ exerts a longitudinal force against the arc plate 402.

Although FIGS. 2 and 3 illustrate only one-half of the arc stack housing 102, the illustrated structure is mirrored on the other half. Those skilled in the art will recognize that either one or two stop members 218 and either one or two locking tabs 222 can be used to position and secure the arc plates 402 without departing from the spirit and scope of the present invention.

In the illustrated embodiment, the arc stack housing 102, including the lower ledge surface 212, the upper surface 214, the resilient rear stop 218, the locking tab 222 and the locking arm 224, is a molded assembly with the elements integrally molded together. With this embodiment, fabrication of the arc stack requires only that the arc plates 402 be inserted and secured in the arc stack housing 102. Additionally, the spring action of the locking arm 224 and the spring action of the rear stop 218 serve to capture and prevent the arc plate 402 from vibrating in the housing 102.

From the foregoing description, it will be recognized by those skilled in the art that an apparatus for securing the arc plates in an arc stack has been provided. The arc stack housing is fabricated of an insulating material and the arc plates are fabricated of a conducting material. The arc plates are positioned in slots in the arc stack during fabrication. The integral locking mechanism secures the arc plates after the plates are fully inserted into the housing.

While the present invention has been illustrated by description of several embodiments and while the illustrative embodiments have been described in considerable detail, it is not the intention of the applicant to restrict or in any way limit the scope of the appended claims to such detail. Additional advantages and modifications will readily appear to those skilled in the art. The invention in its broader aspects is therefore not limited to the specific details, representative apparatus and methods, and illustrative examples shown and described. Accordingly, departures may be made from such details without departing from the spirit or scope of applicant's general inventive concept.

Having thus described the aforementioned invention, we claim:

1. A housing for securing an arc plate, said arc plate including a first longitudinal edge, an opposed second longitudinal edge, a notched first end, and a second end opposed to said notched first end, said housing comprising:
a first support member;
a second support member secured in spaced relation to said first support member;
a first securing ledge protruding from said first support member and toward said second support member;
a first opposing ledge protruding from said first support member and toward said second support member, said first securing ledge and said first opposing ledge defining a first slot adapted to receive said first longitudinal edge of said arc plate;
a second securing ledge protruding from said second support member and toward said first support member;
a second opposing ledge protruding from said second support member and toward said first support member, said second securing ledge and said second opposing ledge defining a second slot adapted to receive said second longitudinal edge of said arc plate;
a stop member extending into one of said first slot and said second slot, said stop member engaging said first end of said arc plate; and
a locking member extending into said first slot to engage said second end of said arc plate.

2. The housing of claim 1 wherein said stop member is resilient and deformable.

3. The housing of claim 1 wherein said locking member includes a resilient member and a tab, said resilient member having a first end fixedly attached to said first securing ledge and having a second end connected to said tab, said tab having an inside face for securing said arc plate in said housing.

4. The housing of claim 1 wherein said first support member, said second support member, said first securing ledge, said second securing ledge, said stop member, and said locking member form an integral molded assembly.

5. A housing for securing an arc plate, said arc plate including a first longitudinal edge, an opposed second longitudinal edge, a notched first end, and a second end opposed to said notched first end, said housing comprising:
a first support member;
a second support member secured in spaced relation to said first support member;
a first securing ledge protruding from said first support member and toward said second support member;
a first opposing ledge protruding from said first support member and toward said second support member, said first securing ledge and said first opposing ledge defining a first slot adapted to receive said first said longitudinal edge of said arc plate;
a second securing ledge protruding from said second support member and toward said first support member;
a second opposing ledge protruding from said second support member and toward said first support member, said second securing ledge and said second opposing ledge defining a second slot adapted to receive said second longitudinal edge of said arc plate;
a stop member extending into one of said first slot and said second slot, said stop member engaging said first end of said arc plate, said stop member being resilient and deformable; and
a locking member extending into said first slot to engage said second end of said arc plate, said locking member having a resilient member and a tab, said resilient member having a first end fixedly attached to said first securing ledge and having a second end connected to said tab, said tab having an inside face in contact with said arc plate.

6. An apparatus for quenching an arc, said apparatus comprising:
a first wall;
a second wall secured in spaced relation to said first wall;
a first slot formed in said first wall and opening toward said second wall;
a second slot formed in said second wall and opening toward said first wall;
a back stop member secured in spaced relation to said first wall;
a locking member secured in spaced relation to said first wall;
an arc plate in slidable communication with said first slot and said second slot;
whereby said arc plate is secured by said first slot, said second slot, said back stop member, and said locking member.

7. The apparatus of claim 6 wherein said back stop member is resilient and deformable, said back stop member being deformed and in contact with said arc plate, whereby said back stop member forces said arc plate against said locking member.

8. The apparatus of claim 6 wherein said locking member includes a resilient member and a tab, said resilient member having a first end fixedly attached to said first wall and having a second end connected to said tab, said tab having an inside face in contact with said arc plate.

9. An apparatus for quenching an arc, said apparatus comprising:
a first wall;
a second wall secured in spaced relation to said first wall;
a first slot formed in said first wall and opening toward said second wall;
a second slot formed in said second wall and opening toward said first wall;
an arc plate in slidable communication with said first slot and said second slot;
a locking member secured in spaced relation to said first wall and including a resilient member and a tab, said resilient member having a first end fixedly attached to said first wall and having a second end connected to said tab, said tab having an inside face in contact with said arc plate;
a back stop member secured in spaced relation to said first wall, said back stop member being resilient and deformable, said back stop member being deformed and in contact with said arc plate, whereby said back stop member pushes said arc plate towards said tab;
whereby said arc plate is secured by said first slot, said second slot, said back stop member, and said locking member.

10. The apparatus of claim 9 wherein said first slot, said second slot, said back stop member, and said locking member form an integral assembly.

11. An apparatus for quenching an arc, said apparatus comprising:
an arc stack housing having a first member secured in spaced relation to a second member, said first member and said second member defining a slot having a back end and an insertion end;
a back stop positioned at said back end;
a locking member positioned at said insertion end;
an arc plate insertable into said slot.

12. An apparatus for quenching an arc, said apparatus comprising:
an arc stack housing;
an arc plate; and
a means for securing said arc plate in said arc stack housing.

13. The apparatus of claim 12 further comprising a means for preventing said arc plate from vibrating in said arc stack housing.
